(19) United States
(12) Patent Application Publication
(10) Pub. No.: US 2005/0056219 A1
(43) Pub. Date: Mar. 17, 2005

(54) Formation of a metal-containing film by sequential gas exposure in a batch type processing system

(75) Inventors: Anthony Dip, Austin, TX (US); Michael Toeller, Austin, TX (US); Kimberly G. Reid, Austin, TX (US)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 10/662,522

(22) Filed: Sep. 16, 2003

(51) Int. Cl. C23C 16/00

(52) U.S. Cl. 118/722; 427/248.1

(57) ABSTRACT

A method is provided for forming a metal-containing film on a substrate by a sequential gas exposure process in a batch type processing system. A metal-containing film can be formed on a substrate by providing a substrate in a process chamber of a batch type processing system, heating the substrate, sequentially flowing a pulse of a metal-containing precursor gas and a pulse of a reactant gas in the process chamber, and repeating the flowing processes until a metal-containing film with desired film properties is formed on the substrate. The method can form a metal-oxide film, for example HfO₂ and ZrO₂, a metal-oxynitride film, for example HfₓO_{z}N_{w}, and HfₓO_{z}N_{w}, a metal-silicate film, for example HfₓSi_{y}O_{z} and ZrₓSi_{y}O_{z}, and a nitrogen-containing metal-silicate film, for example HfₓSi_{y}O_{z}N_{w} and ZrₓSi_{y}O_{z}N_{w}. A processing tool containing a batch type processing system for forming a metal-containing film by a sequential gas exposure process is provided.

### FIELD OF THE INVENTION

The present invention relates to semiconductor processing, and more particularly, to a sequential gas exposure process for forming a metal-containing film in a batch type processing system.

### BACKGROUND OF THE INVENTION

High dielectric constant (high-k) materials with low equivalent oxide thickness (EOT) and very low leakage currents, are likely to replace silicon dioxide (SiO₂) dielectric layers in the semiconductor industry. High-k metal-oxides can provide the required capacitance at a considerably larger physical thickness than SiO₂, thus allowing the reduction of the gate leakage current by suppression of direct tunneling. Binary oxides such as hafnium oxide (HfO₂) and zirconium oxide (ZrO₂), metal-silicates such as hafnium silicate (HfₓSi_{y}O_{z}) and zirconium silicate (ZrₓSi_{y}O_{z}), alumina (Al₂O₃), and lanthanide oxides, are promising metal-oxide high-k materials for gate stack applications.

Precise control of the high-k film growth, the evolution of the interface between the silicon and the high-k film, and the thermal stability of the gate stack are key elements in the integration of high-k films into semiconductor applications. The present inventors have recognized that these key elements of high-k films have largely been studied with respect to single wafer film growth. The present inventors have further recognized, however, that single wafer processing is not likely to provide a cost effective mechanism for the semiconductor industry's integration of metal containing high-k films with semiconductor devices.

### SUMMARY OF THE INVENTION

An object of the present invention is to provide a cost effective mechanism for integrating metal-containing films with semiconductor applications.

Another object of the present invention is to provide a method and system for forming high-k films on a semiconductor wafer in a batch type processing system.

These and/or other objects of the present invention may be provided by a method for forming a metal-containing film on a substrate by providing in a process chamber of a batch type processing system, heating the substrate, flowing a pulse of a metal-containing precursor gas in the process chamber, flowing a pulse of a reactant gas in the process chamber, and repeating the flowing processes until a metal-containing film with desired film properties is formed on the substrate. The metal-containing film can contain a metal-oxide film, a metal-oxynitride film, a metal-silicate film, or a nitrogen-containing metal-silicate film.

In another aspect of the invention, a processing tool is provided for forming a metal-containing film. The processing tool contains a transfer system configured for providing a substrate in a process chamber of a batch type processing system, a heater for heating the substrate, a gas injection system configured for flowing a pulse of a metal-containing precursor gas in the process chamber, flowing a pulse of a reactant gas in the process chamber, and repeating the flowing processes until a metal-containing film with desired film properties is formed on the substrate. The processing system further contains a controller configured to control the processing tool.

### BRIEF DESCRIPTION OF THE DRAWINGS

In the accompanying drawings:

FIG. 1A shows a simplified block diagram of a batch type processing system for forming a metal-containing film on a substrate according to an embodiment of the invention;

FIG. 1B shows a simplified block diagram of a batch type processing system for forming a metal-containing film on a substrate according to another embodiment of the invention;

FIG. 2 shows a simplified block diagram of a processing tool according to an embodiment of the invention;

FIG. 3A shows a flow diagram for forming a metal-containing film on a substrate according to an embodiment of the invention;

FIG. 3B schematically shows a sequential gas exposure process for forming a metal-containing film on a substrate according to an embodiment of the invention;

FIG. 4A shows a flow diagram for forming a metal-containing film on a substrate according to another embodiment of the invention;

FIG. 4B schematically shows a sequential gas exposure process for forming a metal-containing film on a substrate according to another embodiment of the invention;

FIG. 5 schematically shows a sequential gas exposure process for forming a metal-containing film on a substrate according to another embodiment of the invention;

FIG. 6 shows a transmission electron micrograph (TEM) of a HfO₂ film formed according to an embodiment of the invention;

FIG. 7 shows effective oxide thickness (EOT) of HfO₂ films as a function of optical thickness according to an embodiment of the invention;

FIG. 8 shows a C-V curve for a HfO₂ film formed according to an embodiment of the invention;

FIG. 9 shows an I-V curve for a HfO₂ film formed according to an embodiment of the invention;

FIG. 10 shows thickness and with-in-wafer (WIW) uniformity of HfO₂ films as a function of gas exposure time according to an embodiment of the invention;

FIG. 11 shows thickness and WIW uniformity of HfO₂ films as a function of number of gas exposure cycles according to an embodiment of the invention;

FIG. 12A shows deposition rate of HfO₂ films as a function of substrate temperature according to an embodiment of the invention;

FIG. 12B shows deposition rate of HfO₂ films as a function of substrate temperature according to an embodiment of the invention;

FIG. 13 shows WIW uniformity of HfO₂ films as a function of substrate temperature according to an embodiment of the invention; and

FIG. 14 shows a general purpose computer which may be used to implement the present invention.

### DETAILED DESCRIPTION OF THE INVENTION

As noted in the Background of the Invention section above, formation of a metal-containing high-k film on a single substrate will not provide a cost effective mechanism for integrating such films with semiconductor devices. Nevertheless, formation of such high-k films on multiple wafers in a batch type processing system has gone largely unstudied, perhaps due to the difficult problem of providing uniform process results at different wafer positions in a batch type process chamber. Thus, the present inventors have conducted experiments to analyze the effect of different batch type process parameters on the variation of film thickness, uniformity of wafer coverage and deposition rate of metal containing high-k films at different wafer positions of a batch type processing system. As a result of such experiments and analysis, the present inventors have discovered that sequential gas exposure provides a feasible mechanism for forming a metal containing film on a plurality of substrates in a batch processing chamber.

In the sequential gas exposure method, a pulse of a metal-containing precursor gas is flowed in a process chamber containing a substrate to be processed. When the substrate is exposed to the gas pulse, the metal-containing precursor (or fragment of the metal-containing precursor) can chemisorb on the surface of the substrate in a self-limiting process until all of the available surface adsorption sites are occupied. The metal-containing precursor can be an organic or an inorganic molecule containing ligands that provide steric hindrance by blocking or occupying surface bonding sites, thereby preventing buildup of multiple layers until the ligands are removed or modified by a reactant gas. Excess metal-containing precursor can be removed from the process chamber by purging the process chamber with a purge gas and by evacuating the process chamber. Subsequently, the substrate can be exposed to a gas pulse of a reactant gas capable of chemically reacting with the adsorbed portion of the metal-containing precursor.—Excess reactant gas can be removed from the process chamber by purging the process chamber with purge gas and by evacuating the process chamber. The sequential gas exposure process can be repeated until a metal-containing film with desired film properties is formed on a substrate. As further discussed below, the present inventors have discovered that such a sequential gas exposure method can be performed at appropriate process parameters in a batch processing system to form metal containing high-k films having acceptably constant properties across all wafers in the batch.

In particular, in one embodiment of the invention, a metal-containing film can be formed on a substrate in a sequential gas exposure process using isothermal heating conditions in batch type processing system. In the sequential gas exposure process, substrates are provided in a batch type process chamber, the chamber pressure lowered using a vacuum pumping system, and the chamber temperature and pressure stabilized. A substrate (wafer) can be loaded into a batch type process chamber that is at a temperature below which substrate oxidation occurs and where the process chamber contains an ambient containing about 1% oxygen. These process conditions can be effective in removing organic contamination from a substrate. In addition, several pump/purge cycles can be performed using an inert gas. Alternately, the substrate can be exposed to an ozone (O₃) treatment. Next, the process chamber temperature and process chamber pressure can be adjusted to the desired values in an inert ambient to avoid substrate oxidation under non-equilibrium conditions. When the process temperature is reached, the substrate can be processed for a time period that results in formation of a metal-containing film on the substrate. At the end of the process, the process chamber can be evacuated and purged with an inert gas, and the substrate removed from the process chamber.

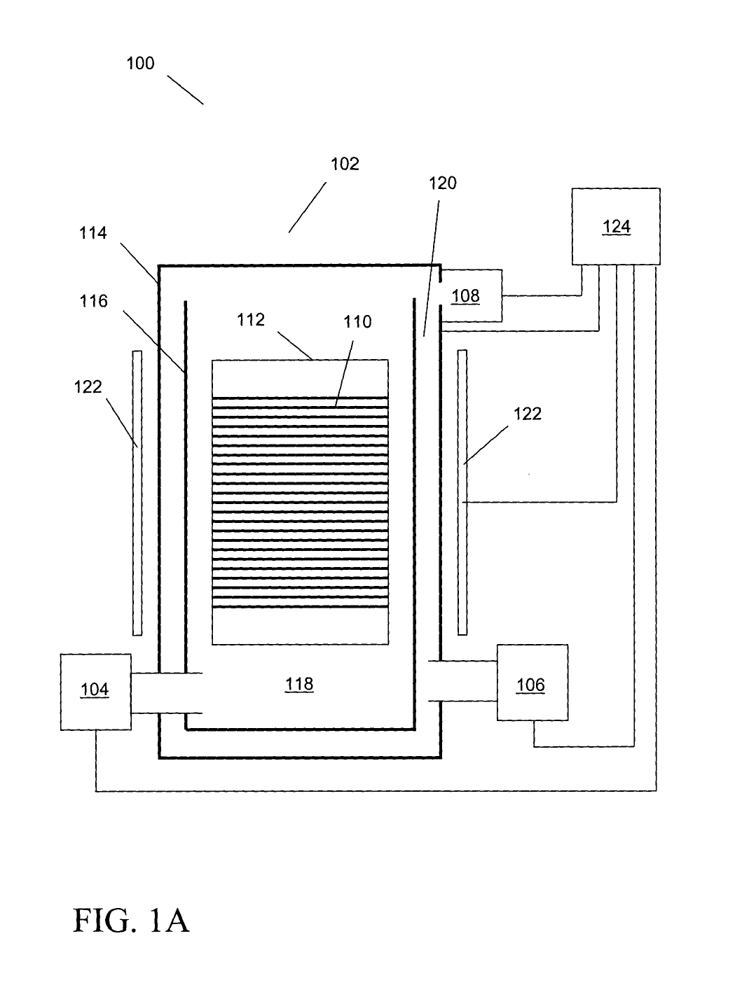

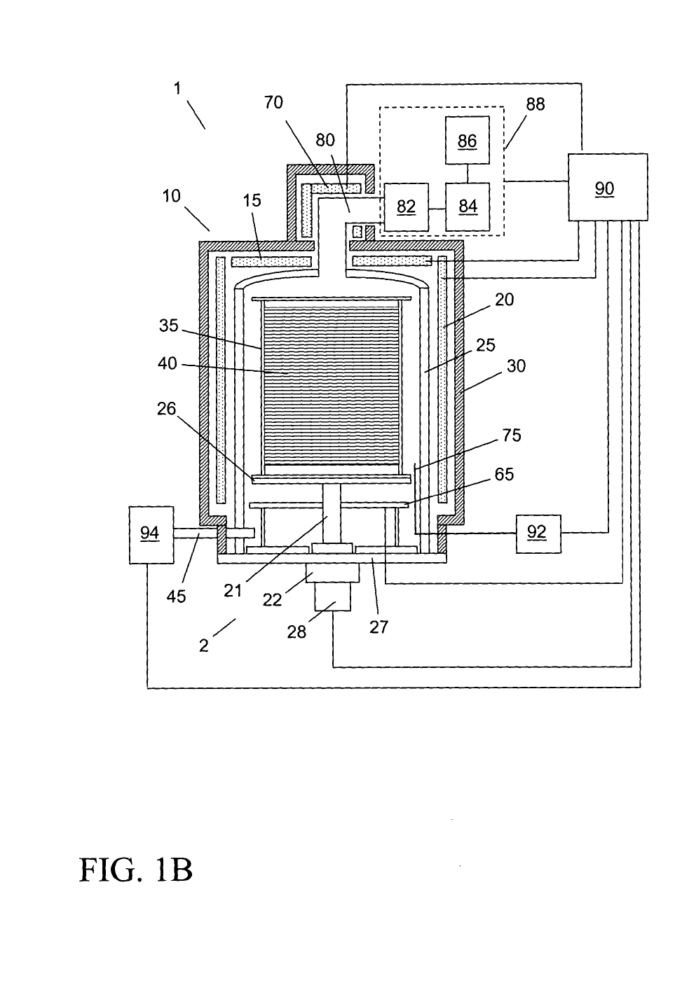

Referring now to the drawings, FIG. 1A shows a simplified block diagram of a batch type processing system for forming a metal-containing film according to an embodiment of the invention. The batch type processing system 100 includes a process chamber 102, a gas injection system 104, a heater 122, a vacuum pumping system 106, a process monitoring system 108, and a controller 124. Multiple substrates 110 can be loaded into the process chamber 102 and processed using substrate holder 112. Furthermore, the process chamber 102 includes an outer section 114 and an inner section 116. In one embodiment of the invention, the inner section 116 can be a process tube.

The gas injection system 104 can introduce gases into the process chamber 102 for purging the process chamber 102, and for preparing, cleaning, and processing the substrates 110. The gas injection system 104 can, for example, include a liquid delivery system (LDS) that contains a vaporizer to vaporize a metal-containing precursor liquid. The vaporized liquid can be flowed into the process chamber 102 with the aid of a carrier gas. Alternately, the gas injection system can include a bubbling system where a carrier gas is bubbled through a reservoir containing the metal-containing precursor. A plurality of gas supply lines can be arranged to flow gases into the process chamber 102. The gases can be introduced into volume 118, defined by the inner section 116, and exposed to substrates 110. Thereafter, the gases can flow into the volume 120, defined by the inner section 114 and the outer section 116, and exhausted from the process chamber 102 by the vacuum pumping system 106.

Substrates 110 can be loaded into the process chamber 102 and processed using substrate holder 112. The batch type processing system 100 can allow for a large number of tightly stacked substrates 110 to be processed, thereby resulting in high substrate throughput. A substrate batch size can, for example, be about 100 substrates (wafers), or less. Alternately, the batch size can be about 25 substrates, or less. The process chamber 102 can, for example, process a substrate of any diameter, such as a substrate with a diameter greater than about 195 mm, e.g., a 200 mm substrate, a 300 mm substrate, or an even larger substrate. The substrates 110 can, for example, include semiconductor substrates (e.g. Si or compound semiconductor), LCD substrates, and glass substrates. In addition to clean substrates, substrates with thin interfacial films formed thereon can be utilized, including but not limited to, oxide films (native or thermal oxides), nitride films, oxynitride films, and mixtures thereof. The thin interfacial films can, for example, be a few angstrom (A) thick and be formed in a self-limiting process at low process pressure. In one example, a thin oxynitride interfacial film can be formed at a substrate temperature between about 700° and about 800° C. using a dilute NO gas and process pressure of 5 Torr.

The batch type processing system 100 can be controlled by a controller 124 capable of generating control voltages sufficient to communicate and activate inputs of the batch type processing system 100 as well as monitor outputs from the batch type processing system 100. Moreover, the controller 124 can be coupled to and exchange information with process chamber 102, gas injection system 104, heater 122, process monitoring system 108, and vacuum pumping system 106. For example, a program stored in the memory of the controller 124 can be utilized to control the aforementioned components of the batch type processing system 100 according to a stored process recipe. One example of controller 124 is a DELL PRECISION WORKSTATION 610™, available from Dell Corporation, Dallas, Tex.

Real-time process monitoring can be carried out using process monitoring system 108. In general, the process monitoring system 108 is a versatile monitoring system and can, for example, include a mass spectrometer (MS) or a Fourier Transform Infra-red (FTIR) spectrometer. The process monitoring system 108 can provide qualitative and quantitative analysis of the gaseous chemical species in the process environment. Process parameters that can be monitored include gas flows, gas pressure, ratios of gaseous species, and gas purities. These parameters can be correlated with prior process results and various physical properties of the metal-containing film.

FIG. 1B shows a simplified block diagram of a batch type processing system for forming a metal-containing film according to another embodiment of the invention. The batch type processing system 1 contains a process chamber 10 and a process tube 25 that has an upper end connected to a exhaust pipe 80, and a lower end hermetically joined to a lid 27 of cylindrical manifold 2. The exhaust pipe 80 discharges gases from the process tube 25 to a vacuum pumping system 88 to maintain a pre-determined atmospheric or below atmospheric pressure in the processing system 1. A substrate holder 35 for holding a plurality of substrates (wafers) 40 in a tier-like manner (in respective horizontal planes at vertical intervals) is placed in the process tube 25. The substrate holder 35 resides on a turntable 26 that is mounted on a rotating shaft 21 penetrating the lid 27 and driven by a motor 28. The turntable 26 can be rotated during processing to improve overall film uniformity, alternately, the turntable can be stationary during processing. The lid 27 is mounted on an elevator 22 for transferring the substrate holder 35 in and out of the reaction tube 25. When the lid 27 is positioned at its uppermost position, the lid 27 is adapted to close the open end of the manifold 2.

A plurality of gas supply lines can be arranged around the manifold 2 to supply a plurality of gases into the process tube 25 through the gas supply lines. In FIG. 1B, only one gas supply line 45 among the plurality of gas supply lines is shown. The gas supply line 45 is connected to a gas injection system 94. A cylindrical heat reflector 30 is disposed so as to cover the reaction tube 25. The heat reflector 30 has a mirror-finished inner surface to suppress dissipation of radiation heat radiated by main heater 20, bottom heater 65, top heater 15, and exhaust pipe heater 70. A helical cooling water passage (not shown) is formed in the heat reflector 10 as cooling medium passage.

A vacuum pumping system 88 includes a vacuum pump 86, a trap 84, and automatic pressure controller (APC) 82. The vacuum pump 86 can, for example, include a dry vacuum pump capable of a pumping speed up to 20,000 liters per second (and greater). During processing, gases can be introduced into the process chamber 10 via the gas injection system 94 and the process pressure can be adjusted by the APC 82. The trap 84 can collect unreacted precursor material and by-products from the process chamber 10.

The process monitoring system 92 includes a sensor 75 capable of real-time process monitoring and can, for example, include a MS or a FTIR spectrometer. A controller 90 includes a microprocessor, a memory, and a digital I/O port capable of generating control voltages sufficient to communicate and activate inputs to the processing system 1 as well as monitor outputs from the processing system 1. Moreover, the controller 90 is coupled to and can exchange information with gas injection system 94, motor 28, process monitoring system 92, heaters 20, 15, 65, and 70, and vacuum pumping system 88. As with the controller 124 of FIG. 1A, the controller 90 may be implemented as a DELL PRECISION WORKSTATION 610™.

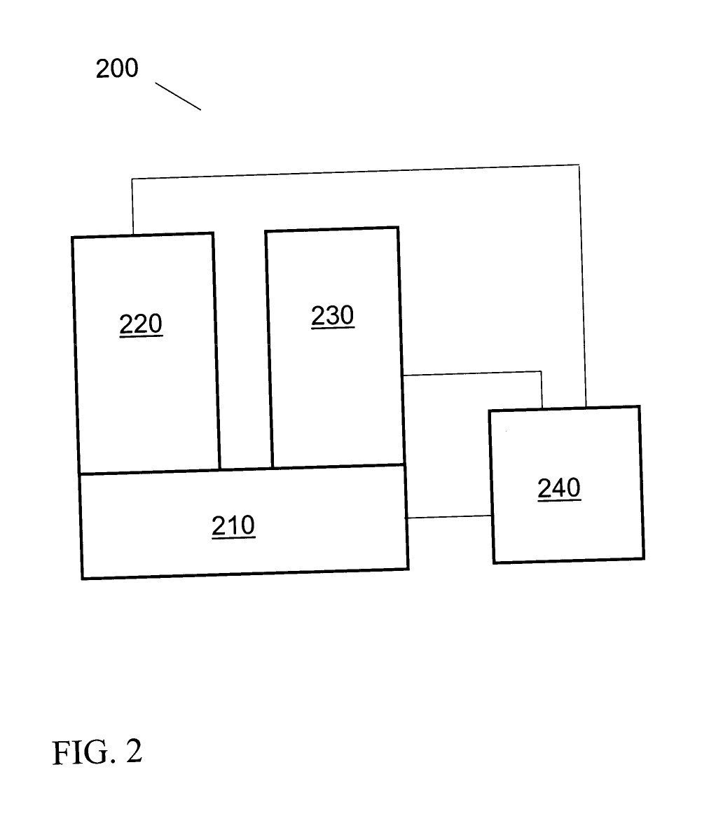

FIG. 2 shows a simplified block diagram of a processing tool according to an embodiment of the invention. The processing tool 200 includes processing systems 220 and 230, a (robotic) transfer system 210 configured for transferring substrates within the processing tool 200, and a controller 240 configured to control the processing tool 200. In another embodiment of the invention, the processing tool 200 can include a single processing system or, alternately, can include more than two processing systems. In FIG. 2, the processing systems 220 and 230 can, for example, perform at least one of the following processes: (a) form an interfacial film on a substrate, (b) form a metal-containing film on a substrate in a sequential gas exposure process, (c) perform an annealing process, (d) form an electrode layer, and (e) determine the properties of at least one of a substrate, an interfacial film, a metal-containing film formed in a sequential gas exposure process, and an electrode layer. With regard to forming the electrode layer, in addition to the traditional doped Si and poly-Si, the electrode film can, for example, include at least one of W, Al, TaN, TaSiN, HfN, HfSiN, TiN, TiSiN, Re, Ru, and SiGe, and can be deposited using various well-known deposition processes. In one embodiment of the invention, each of the processes (a)-(e) can be performed in different processing systems. In another embodiment of the invention, at least two of the processes (a)-(e) are carried out in the same processing system. In one embodiment of the invention, at least one of the processing systems can be a batch type processing system.

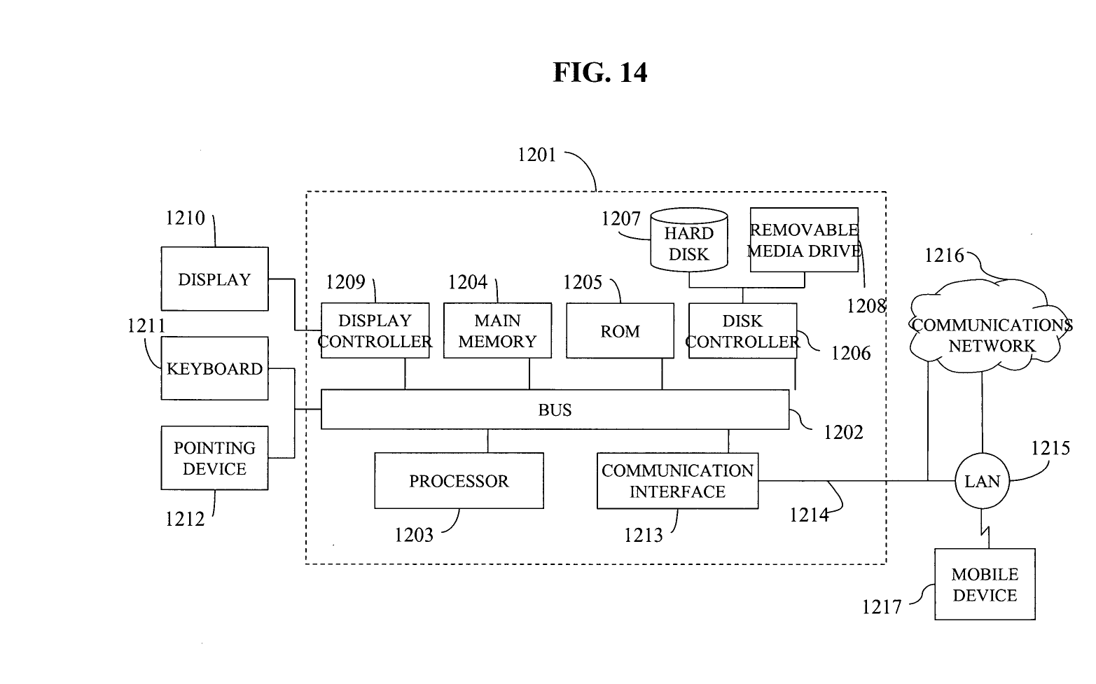

As with the controllers of FIGS. 1A and 1B, the controller 240 may be implemented as a DELL PRECISION WORKSTATION 610™. Moreover, the controller of any of FIGS. 1A, 1B and 2 may be implemented as a general purpose computer system such as that described with respect to FIG. 14.

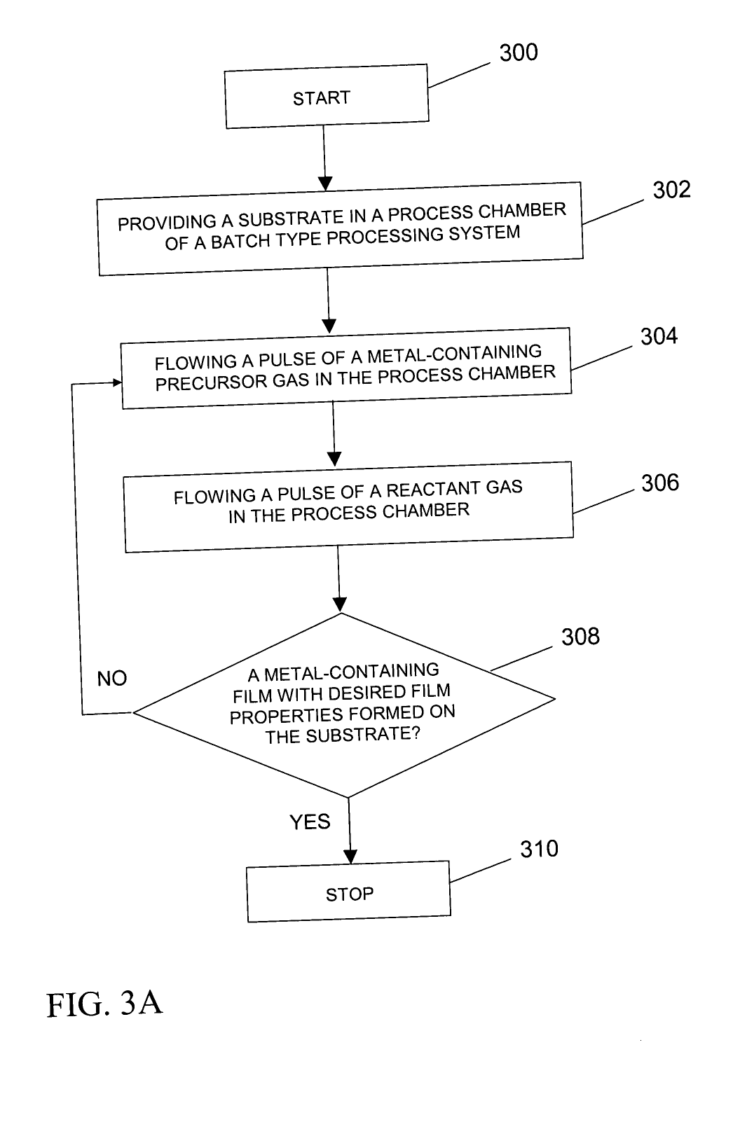

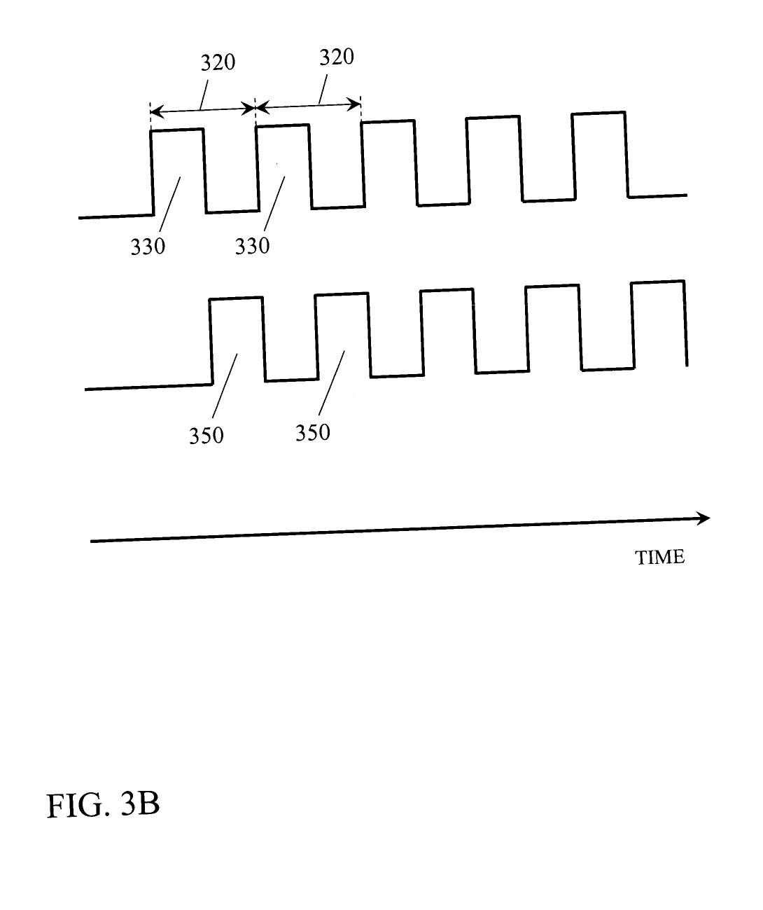

FIG. 3A shows a flow diagram for forming a metal-containing film on a substrate according to an embodiment of the invention. In 300, the process is started. In 302, a substrate is provided in a process chamber of a batch type processing system. The batch type processing system may be the system described in FIG. 1A or FIG. 1B, for example, and may be provided as part of a processing tool such as that described in FIG. 2. In 304, a pulse of a metal-containing precursor is flowed in the process chamber. As noted above, the precursor gas can chemisorb on the surface of the substrate in a self-limiting process until all of the available surface adsorption sites are occupied. In one embodiment of the invention, the metal-containing precursor can contain a metal alkoxide. The metal alkoxide precursor can, for example, contain M(OR)₄, where M is a metal and the alkyl group R can be selected from a methyl ligand (Me), an ethyl ligand (Et), a propyl ligand (Pr), and a tert-butyl ligand (Bu^{t}). The metal M can, for example, be selected from hafnium and zirconium, and the metal-containing film can include at least one of HfO₂, ZrO₂, and mixtures thereof. In one example, the M(OR)₄ precursor can be selected from Hf(OBu^{t})₄ and Zr(OBu^{t}) ₄. The metal alkoxide can, for example, be selected from M(OR)₂(mmp)₂ and M(mmp)₄, where mmp is a OCMe₂CH₂OMe ligand, M is a metal, and R is an alkyl group. R can, for example, be a methyl ligand, an ethyl ligand, a propyl ligand, or a tert-butyl ligand. The metal M can, for example, be selected from hafnium and zirconium.

In another embodiment of the invention, the metal-containing precursor can contain a metal alkylamide. The metal alkylamide can, for example, be selected from M(NR₂)₄, where M is a metal and R is an alkyl group. R can, for example, be a methyl ligand, an ethyl ligand, a propyl ligand, or a tert-butyl ligand. The metal M can, for example, be selected from hafnium and zirconium. Examples of metal alkylamides include tetrakis(diethylamino)hafnium (TDEAH, Hf(NEt₂)₄) and tetrakis(ethylmethylamino)hafnium (TEMAH, Hf(NEtMe)₄).

Once the pulse of precursor gas has been flowed, a pulse of a reactant gas is then flowed in the process chamber as shown by step 306. The reactant gas can include a gas that is capable of reacting with a metal-containing precursor on the substrate and can aid in the removal of reaction by-products from the substrate. The reactant gas can include at least one of a reducing gas, an oxidizing gas, and may also include an inert gas. The oxidizing gas can contain an oxygen-containing gas. The oxygen-containing gas can, for example, contain at least one of O₂, O₃, H₂O₂, H₂O, NO, N₂O, and NO₂. The reducing gas can contain a hydrogen-containing gas, for example H₂. Alternately the reducing gas can contain a silicon-containing gas, for example, silane (SiH₄), disilane (Si₂H₆), hexachlorosilane (Si₂Cl₆), and dichlorosilane (SiCl₂H₂). Alternately, the reducing gas can contain a boron-containing gas, for example a boron-containing gas with the general formula BₓH₃ₓ. This includes, for example, borane (BH₃), diborane (B₂H₆), triborane (B₃H₉), and others. Alternately, the reducing gas can contain a nitrogen-containing gas, for example ammonia (NH₃). In addition, the reducing gas can contain more than one of the above-mentioned gases. The carrier gas and the purge gas can contain an inert gas. The inert gas can, for example, contain at least one of Ar, He, Ne, Kr, Xe, and N₂.

Once the precursor gas and reactant gas have been flowed into the chamber in step 306, a determination of whether a metal containing film with the desired film properties has been formed on the substrate is made as shown by decision block 308. Film properties can include film thickness, film composition, and electrical properties such as leakage current, electrical hysteresis, and flat band voltage. In one embodiment of the invention, the thickness of the metal-containing film can be less than about 1000 angstrom (A). In another embodiment of the invention, the thickness of the metal-containing film can be less than about 200 A. In yet another embodiment of the invention, the thickness of the metal-containing film can be less than about 50 A. Determination of whether a film with the desired film properties has been formed on the substrate is preferably made by a monitoring system such as the monitoring system described with respect to FIGS. 1A and 1B, for example. Film properties may be determined by directly monitoring the film itself, or properties of the film may be derived from other process parameters and/or chamber conditions.

Where it is determined in step 308 that a metal-containing film with desired film properties has been formed on the substrate, the process ends in 310. Where it is determined that the metal containing film formed on the substrate does not have the desired properties, the process of FIG. 3A returns to step 304 where the cycle of flowing a precursor gas followed by a reactant gas is repeated. FIG. 3B schematically shows repeated gas flows for forming a metal-containing film on a substrate according to an embodiment of the invention. In the process of FIG. 3B, a gas pulse 330 of a metal-containing precursor gas and a gas pulse 350 of a reactant gas are sequentially flowed in a process chamber. A gas exposure cycle 320 includes a gas pulse 330 and a gas pulse 350. The gas exposure cycle 320 can be repeated until a metal-containing film with desired film properties has been formed on the substrate, as determined in step 308 of FIG. 3A.

The present invention may also include flowing at least one of a carrier gas and a purge gas into the process chamber as part of the sequential gas exposure method. Carrier and purge gases can be continuously flowed in the process chamber during processing or, alternately, can be intermittently flowed in the process chamber during processing as will be further described below. In general, the metal-containing precursor gas can be considered to contain a metal-containing precursor and optionally a carrier gas. A carrier gas can aid in the delivery of the metal-containing precursor to the process chamber and can further be used to adjust the process gas partial pressure(s). A purge gas can be selected to efficiently remove, for example, the reactant gas, the metal-containing precursor gas, the carrier gas, and reaction by-products, from the process chamber. During the sequential gas exposure process, gases are continuously being exhausted from the process chamber using a vacuum pumping system.

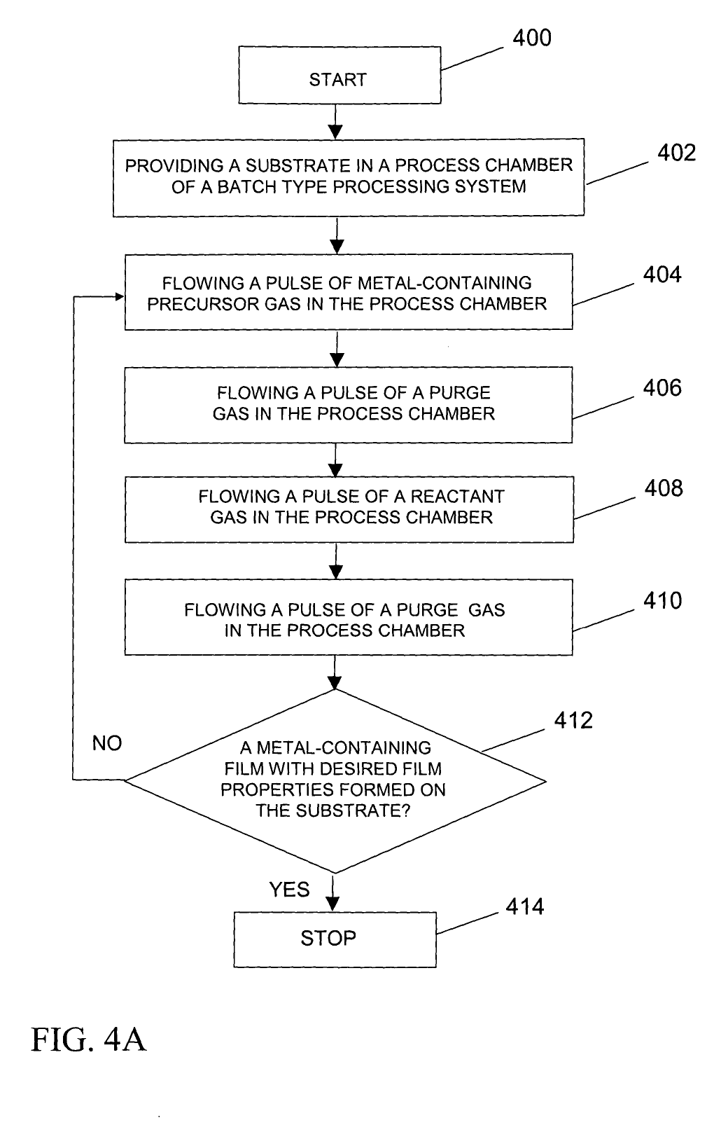

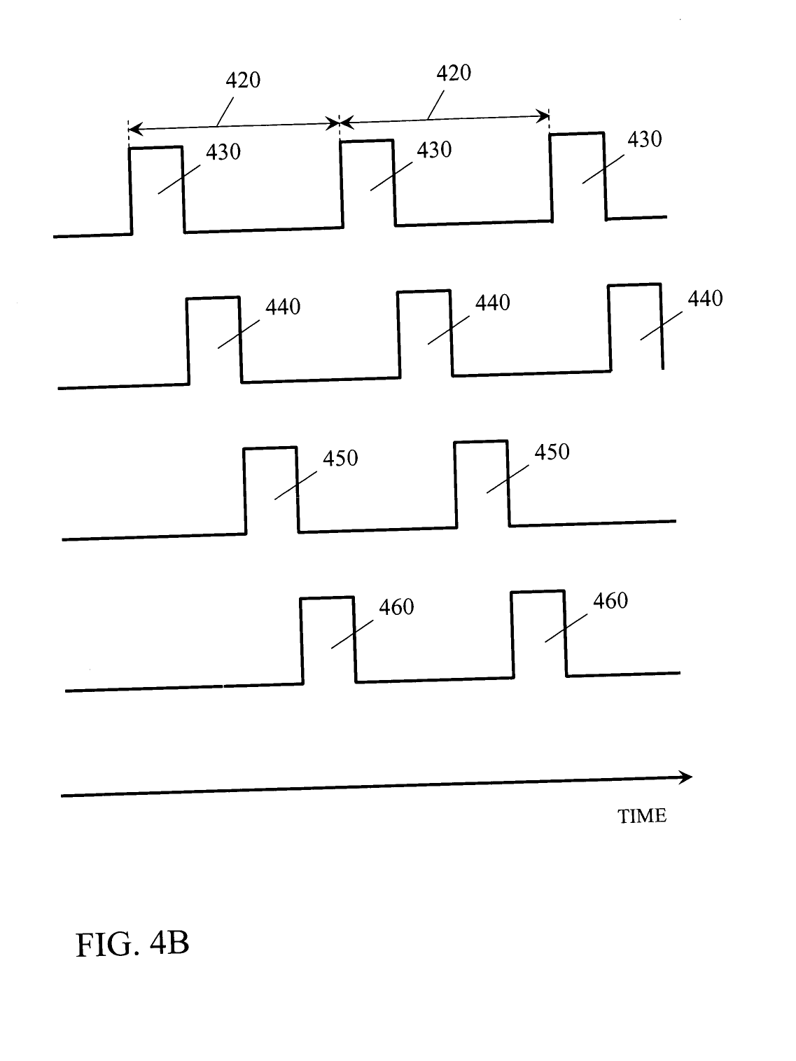

FIG. 4A shows a flow diagram for forming a metal-containing film on a substrate according to another embodiment of the invention wherein a purge gas is used in the process. In 400, the process is started. In 402, a substrate is provided in a process chamber of a batch type processing system. In 404, a pulse of a metal-containing precursor gas is flowed into the process chamber. The metal containing precursor gas of step 404 may be any of the precursor gas types described with respect to Step 304 of FIG. 3B, except, the precursor gas of step 404 may be selected in consideration of a particular purge gas to be used in purging the precursor gas from the chamber. As seen in step 406, a pulse of a purge gas is then flowed into the process chamber. The purge gas of step 406 is preferably selected to efficiently remove the precursor gas of step 404 from the process chamber. In 408, a pulse of a reactant gas is flowed in the process chamber. The reactant gas of step 408 may be any of the precursor gas types described with respect to Step 306 of FIG. 3B, except, the reactant gas of step 408 may be selected in consideration of a particular purge gas to be used in purging the reactant gas from the chamber. As seen in step 410, a pulse of a purge gas is then flowed in the process chamber. The purge gas of step 410 is preferably selected to efficiently remove the reactant gas of step 408 from the process chamber and therefore may be different from the purge gas of step 406.

Once the pulse of purge gas has been flowed into the chamber in step 410, a determination of whether a metal containing film with the desired film properties has been formed on the substrate as shown by decision block 412. As with the process of FIG. 3A, the film may be monitored by a monitoring system directly or properties of the film derived from monitored process parameters and/or other chamber conditions. Where it is determined in step 412 that a metal-containing film with desired film properties has been formed on the substrate, the process ends in 414. Where it is determined that the metal containing film does not have the desired properties, the process of FIG. 4A returns to step 404 where the cycle of flowing a precursor gas followed by a reactant gas is repeated. FIG. 4B schematically shows a repeated sequential gas exposure process for forming a metal-containing film on a substrate according to another embodiment of the invention. In the process, a gas pulse 430 of a metal-containing precursor and a gas pulse 450 of a reactant gas are sequentially flowed in a process chamber. A sequential gas exposure cycle 420 includes a gas pulse 430 and a gas pulse 450. The gas exposure cycle 420 can be repeated until a metal-containing film with desired film properties has been formed on the substrate.

In the embodiment illustrated in FIG. 4B, a purge gas pulse 440 and a purge gas pulse 460 are flowed in a process chamber when a gas pulse 430 of a metal-containing precursor and a gas pulse 450 of a reactant gas are not flowing in the process chamber. A gas exposure cycle 420 includes gas pulses 430, 440, 450, and 460. The gas exposure cycle 420 can be repeated until a metal-containing film with desired film properties has been formed on the substrate. The purge gas pulses 440 and 460 can include the same purge gas or, alternately, they can include different purge gases. The purge gas pulses 440 and 460 can be equal in length or, alternately, they can differ in length.

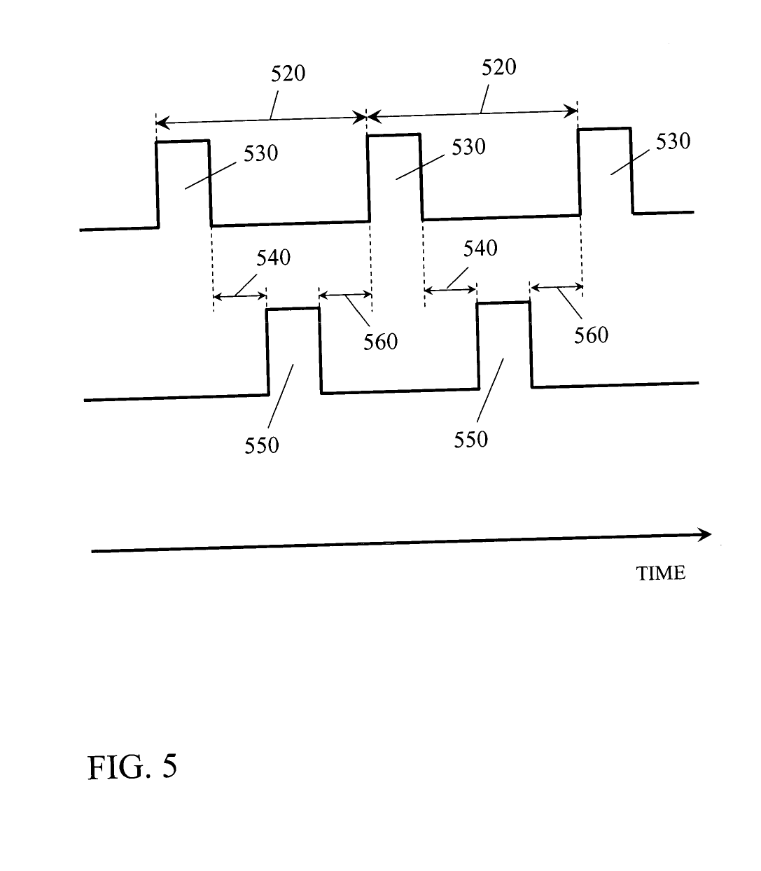

While FIGS. 3B and 4B show a sequential gas exposure process wherein the gas pulses immediately follow one another, the present invention is not limited to such a process. FIG. 5 schematically shows a sequential gas exposure process for forming a metal-containing film on a substrate according to another embodiment of the invention wherein the gas pulses do not immediately follow one another. As seen in this figure, a gas pulse 530 of a metal-containing precursor and a gas pulse 550 of a reactant gas are sequentially flowed in a process chamber with a time lapse 540 and a time lapse 560 occurring before and after the reactant gas pulse, respectively. Time periods 540 and 560 can be equal in length or, alternately, they can differ in length. Thus, a sequential gas exposure cycle 520 of FIG. 5 includes gas pulse 530, time period 540, gas pulse 550, and time period 560. The gas exposure cycle 520 can be repeated until a metal-containing film with desired film properties has been formed on the substrate. During time periods 540 and 560, the process chamber can be purged by a carrier gas or a purge gas by flowing such a gas into the processing chamber during any portion or all of the time periods 540 or 560. Alternatively, no gas can flow in the process chamber during time periods 540 and 560. The purge gases in 540 and 560 can be the same or, alternately, they can be different. In another embodiment of the invention, time periods 540 and 560 can further contain at least one evacuation time period when no gas is flowed into the process chamber.

Thus, the present inventors have discovered a sequential gas exposure process that is effective for forming a metal containing film on a plurality of substrates in a batch processing chamber. It is to be understood that FIGS. 3-5 are exemplary in nature in order to describe the present invention. Suitable process conditions that enable deposition of a metal-containing film with desired film properties can be determined by direct experimentation and/or design of experiments (DOE) by one of ordinary skill in the art having the benefit of the inventive disclosure contained herein. Adjustable process parameters can, for example, include the pulse lengths of the gases, process pressure and temperature, type of reactant gas and metal-containing gas, and relative gas flows.

With regard to pulse length, the pulse lengths of the gases can be independently varied to affect the properties of the metal-containing film formed in accordance with the present invention. For example, the length of a pulse of a metal-containing precursor can be selected to be long enough to expose a sufficient amount of the metal-containing precursor to the substrate surface. The length of the pulse can, for example, depend on the reactivity of the metal-containing precursor, dilution of the metal-containing precursor with a carrier gas, and the flow characteristics of the processing system. The length of a pulse of a reactant gas can be selected to be long enough to expose a sufficient amount of the reactant gas to the substrate surface. The length of the pulse can, for example, depend on the reactivity of the reactant gas, dilution of the reactant gas with a dilution gas, and the flow characteristics of the processing system. The length of a pulse of a purge gas can be selected to be long enough to purge the processing chamber of the metal-containing precursor gas, the reactant gas, a carrier gas, and reaction by-products. The length of the pulse can, for example, depend on the flow characteristics of the processing system, and the pumping speed of the processing system. Moreover, the pulse lengths can be the same in each gas exposure cycle or, alternately, the pulse lengths can vary in each gas exposure cycle. The pulse lengths can, for example, be from about 1 sec to about 500 sec, for example 60 sec. The length of a gas exposure cycle can, for example, be a few minutes.

Similarly, the flow rates, chamber pressure and chamber temperature of the sequential gas exposure process may be varied. A flow rate of a metal-containing precursor liquid into a vaporizer in a liquid delivery system can, for example, be between about 0.05 cubic centimeters per minute (ccm) and about 1 ccm. The reactant gas flow rate can, for example, be between about 100 sccm and about 2000 sccm. The carrier gas flow rate can, for example, be between about 100 sccm and about 10,000 sccm, preferably about 2000 sccm. A purge gas flow rate can, for example, be between about 100 sccm and about 10,000 sccm. The process pressure in the process chamber can, for example, be less than about 10 Torr, preferably between about 0.05 Torr and about 2 Torr. In one embodiment, the process pressure can be about 0.3 Torr. The process pressure in the process chamber can be constant during the process or alternately, the pressure can be varied during processing. The substrate temperature can be between about 100° C. and about 600° C. In one embodiment of the invention, the substrate temperature can, for example, be less than about 200° C., for example about 190° C. The substrate temperature can be kept constant during the process or, alternately, the temperature can be varied during the process.

In addition to variation of process parameters, the process of the present invention may include additional process steps not mentioned with respect to FIGS. 3-5. For example, in one embodiment of the invention, the metal-containing film can be annealed after the sequential gas exposure process to improve the properties of the metal-containing film. The process chamber ambient during annealing can, for example, include a gas containing at least one of N₂, NH₃, NO, N₂O, O₂, O₃, and an inert gas (e.g., He or Ar). The annealing process can, for example, include an anneal at a substrate temperature between about at 150° C. and about 1000° C.

Moreover, the process of the present invention may include additional gas flow steps not described with respect to FIGS. 3-5. For example, the process described above for forming a metal-oxide film, can further contain a process step for flowing a pulse of a nitrogen-containing gas (e.g., NH₃ or N₂O), to form metal-oxynitride film (e.g., MₓO_{z}N_{w}, where M can be Hf or Zr). In still another embodiment of the invention, the process described above for forming a metal-oxide film, can further contain flowing a pulse of a silicon-containing gas (e.g., SiH₄, Si₂H₆, Si₂Cl₆, or SiCl₂H₂), to form a metal-silicate film (e.g., e.g., MₓSi_{y}O_{z}, where M can be Hf or Zr). In yet another embodiment of the invention, the process for forming a metal-silicate film can further include a pulse of a nitrogen-containing gas (e.g., NH₃ or N₂O) to form a nitrogen-containing metal-silicate film (e.g., MₓSi_{y}O_{z}N_{w}, where M can be Hf or Zr). Still further, in one embodiment of the invention, at least one of the flowing processes can be performed a plurality of times in the same gas exposure cycle to increase the content of at least one element in the film. For example, a gas exposure cycle including: Hf(OBu^{t})₄, O₂, SiH₄, O₂, and SiH₄, can be used to form a HfₓSi_{y}O_{z} film with increased Si and O content.

Still further, the inventors have discovered that a sequential gas exposure process according to the invention can be performed where the flow of a reactant gas shown in FIGS. 3-5 is omitted from the process and replaced by a flow of an inert gas. For example, a HfO₂ film can be formed in a sequential gas exposure process using a flow of metal alkoxide precursor (e.g., Hf(OBu^{t})₄) and an inert gas.

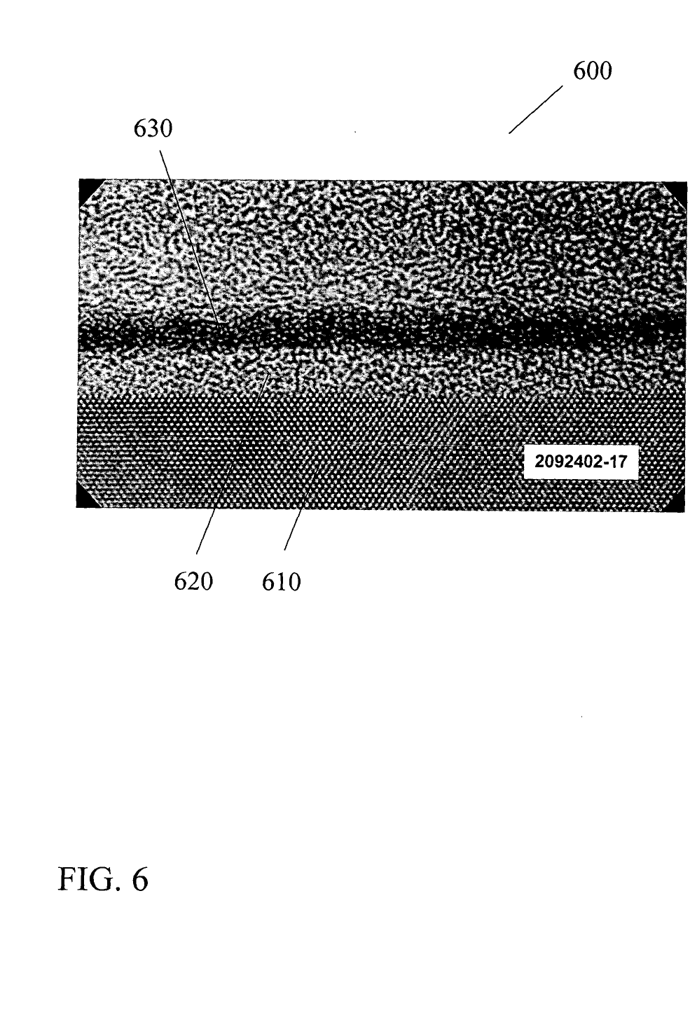

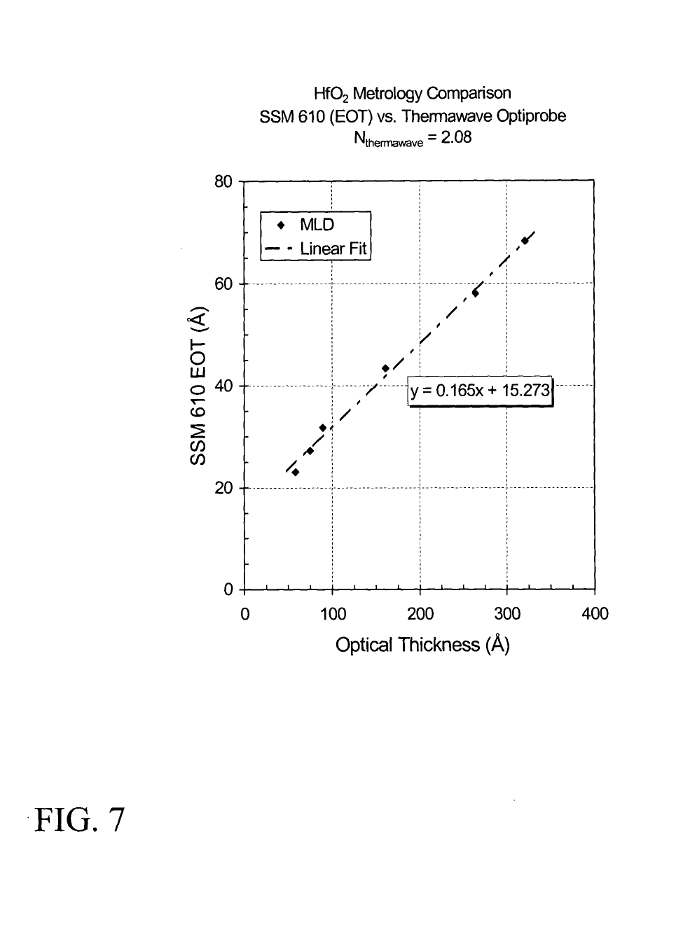

As described above, the sequential gas exposure process of the present invention may be used to form a metal containing film. The metal-containing film can be a stoichiometric metal-oxide film, for example a metal oxide with a chemical formula of MO₂. Alternately, the metal-oxide film can be non-stoichiometric, for example metal rich (e.g., M_{x>1}O₂) or, alternately, oxygen rich (e.g., M_{x<1}O₂). FIG. 6 shows a TEM of a HfO₂ film deposited onto an oxide layer according to an embodiment of the invention. The structure 600 includes a bulk Si substrate 610, a native oxide (SiO₂) film 620, and a HfO₂ film 630. The amorphous HfO₂ film 630 was deposited using a Hf(OBu^{t})₄ precursor in a sequential gas exposure process. The HfO₂ film 630 is about 17 A thick and the native oxide film 620 is about 25 A thick. As seen in FIG. 6, the HfO₂ film 630 has no visible pinholes and the processing conditions are compatible with Cu integration. In addition, as shown in FIGS. 7-9, HfO₂ films formed in accordance with the present invention provide a high dielectric constant, as well as the desirable capacitance and leakage current properties with high-k films.

FIG. 7 shows effective oxide thickness (EOT) of HfO₂ films as a function of optical thickness according to an embodiment of the invention. The EOT was measured using a SSM 610 FastGate Electrical Characterization System (Solid State Measurements, Pittsburgh, Pa.) and the optical thickness was measured using a Thermawave Optiprobe (Thermawave, Fremont, Calif.) and an index of refraction of 2.08. A linear fit of the data shows a dielectric constant (k) greater than 20 for the HfO₂ film and a zero offset of about 15 A due to a native oxide layer on the substrate.

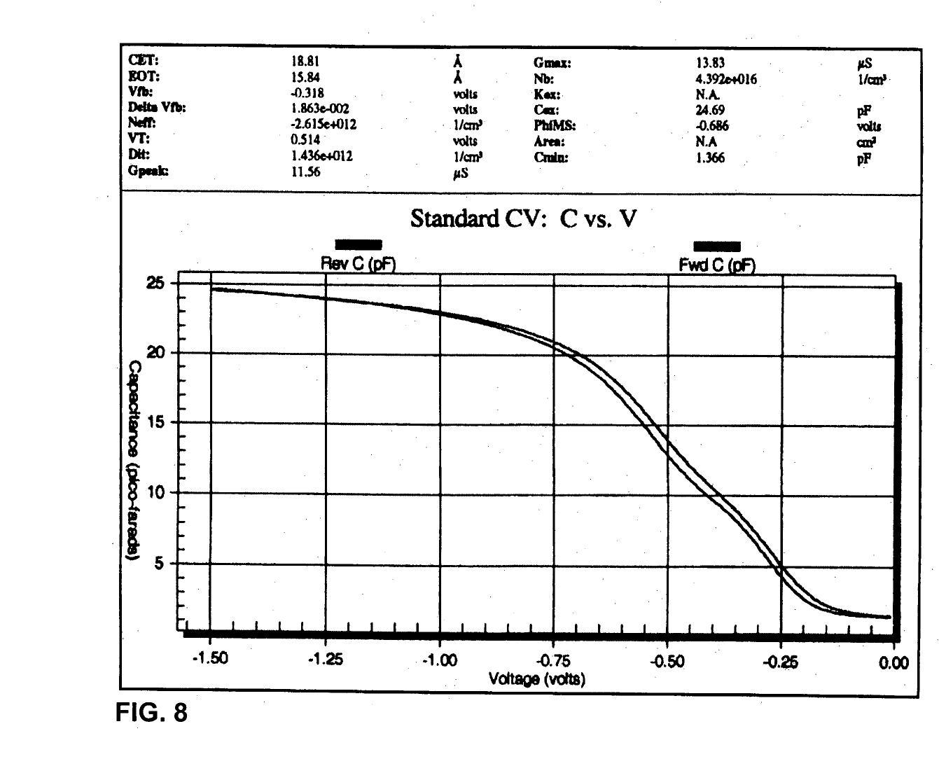

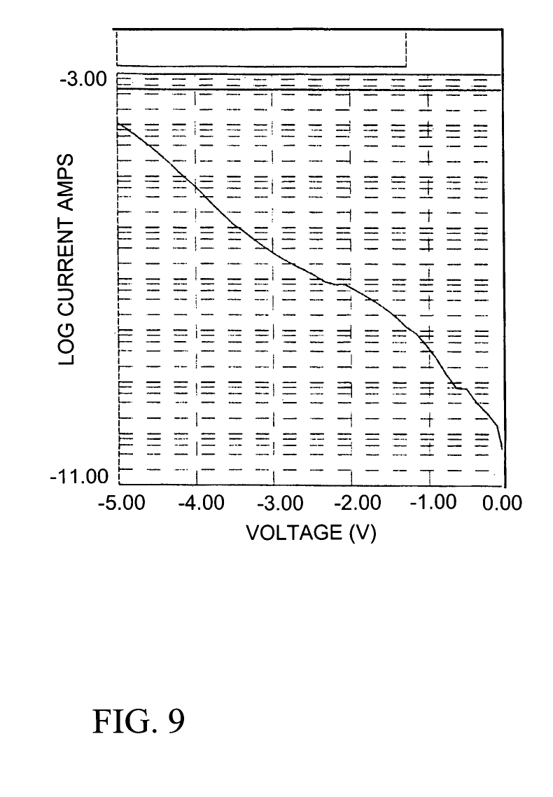

FIG. 8 shows a C-V curve for a HfO₂ film deposited according to an embodiment of the invention. The unannealed HfO₂ film was deposited on a Si substrate and the C-V curve shows a hysteresis (ΔVFB) of about 18 mV in the flat band voltage. The total thickness of the HfO₂ film was measured by ellipsometry to be 15.8 A, the EOT was 15.8 A and the capacitance equivalent thickness was 18.8 A. FIG. 9 shows an I-V curve for a HfO₂ film deposited according to an embodiment of the invention. The unannealed HfO₂ film was deposited onto a Si substrate and the I-V curve shows a leakage current of about 10⁻⁸ A/cm² at V_{FB}−V=−1.318V.

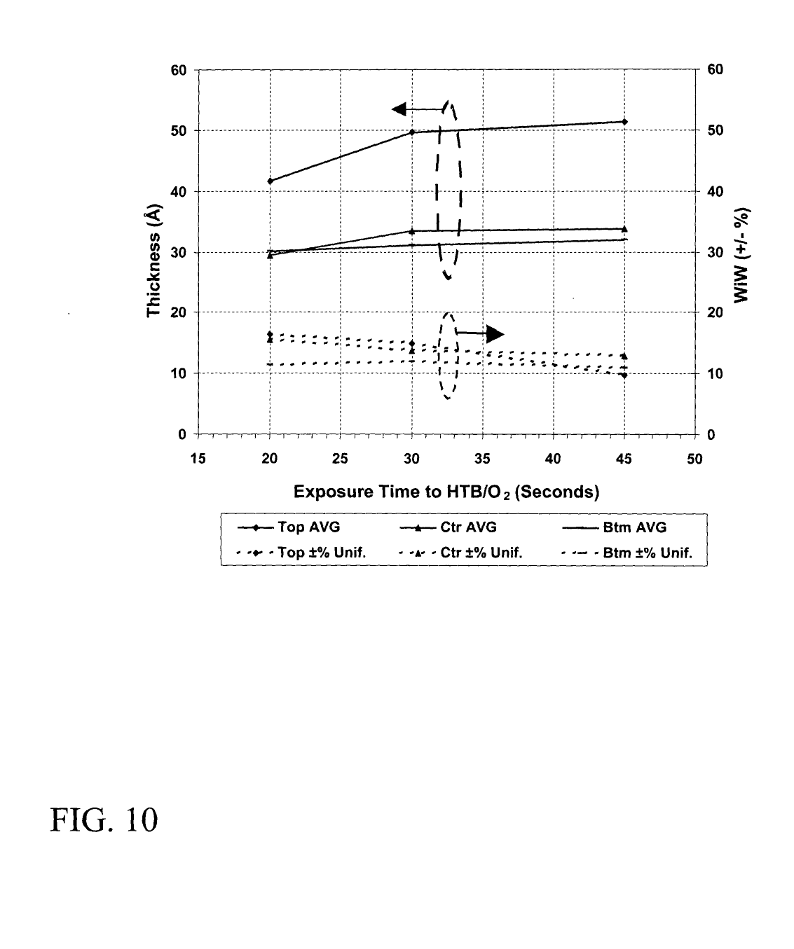

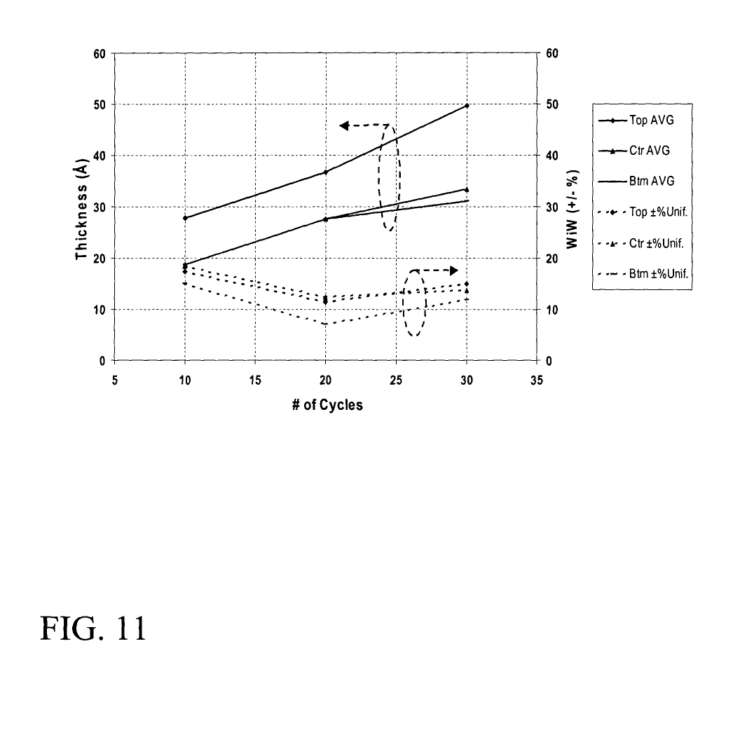

Moreover, the sequential gas exposure process of the resent invention provides batch formation of metal containing high-k films having desirable film properties at acceptable variations over an entire batch. FIG. 10 shows thickness and with-in-wafer (WIW) uniformity of HfO₂ films as a function of gas exposure time according to an embodiment of the invention. The HfO₂ films were deposited using equal pulse durations of a precursor gas containing Hf(OBu^{t})₄ and N₂ dilution gas, and a reactant gas containing O₂ and N₂ dilution gas, in a sequential gas exposure process. The reactant gas contained an O₂ flow rate was 250 sccm and a N₂ dilution gas flow rate of 1250 sccm. The Hf(OBu^{t})₄ liquid flow rate into a vaporizer was 0.1 ccm and the precursor gas further contained a N₂ dilution gas flow rate of 1250 sccm. The substrate temperature was 200° C. and the process pressure was 0.3 Torr. The number of gas exposure cycles was 30. The thickness of the HfO₂ films was measured for substrates located near the top, the middle, and the bottom of the substrate holder. The data in FIG. 10 shows that HfO₂ films from about 30 A to about 50 A thick are formed with a WIW uniformity of about 10-15%. FIG. 11 shows thickness and WIW uniformity for HfO₂ films as a function of substrate temperature according to an embodiment of the invention. The data in FIG. 11 shows that HfO₂ films from about 20 A to about 50 A thick HfO₂ films are formed with a WIW uniformity better than about 20%.

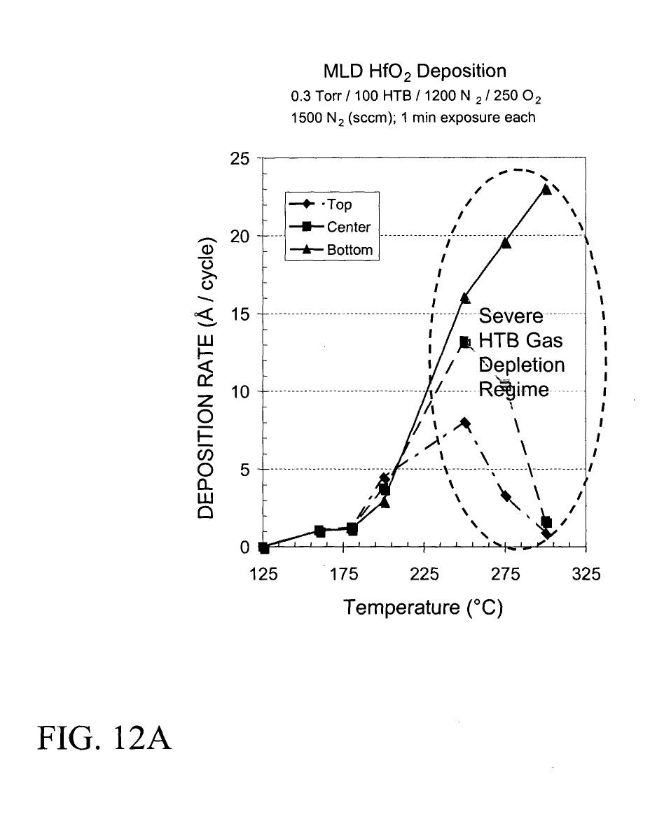

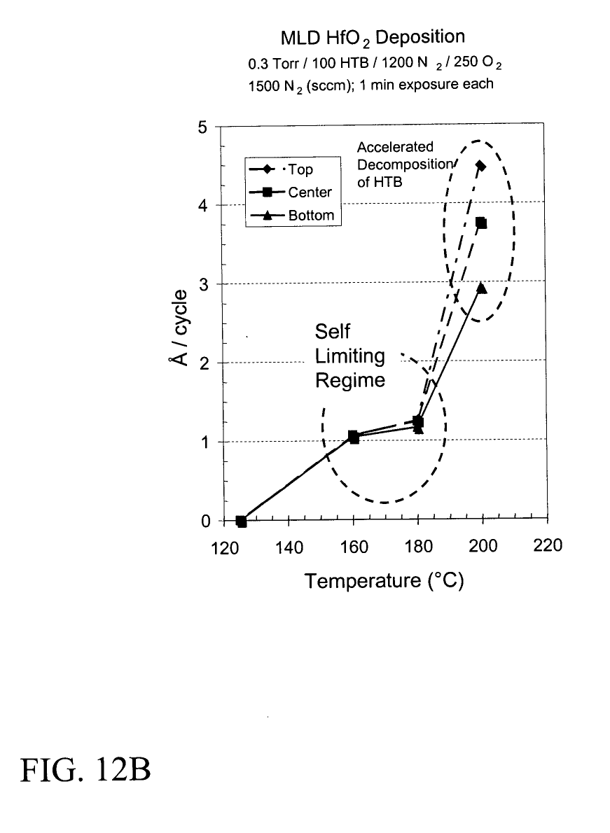

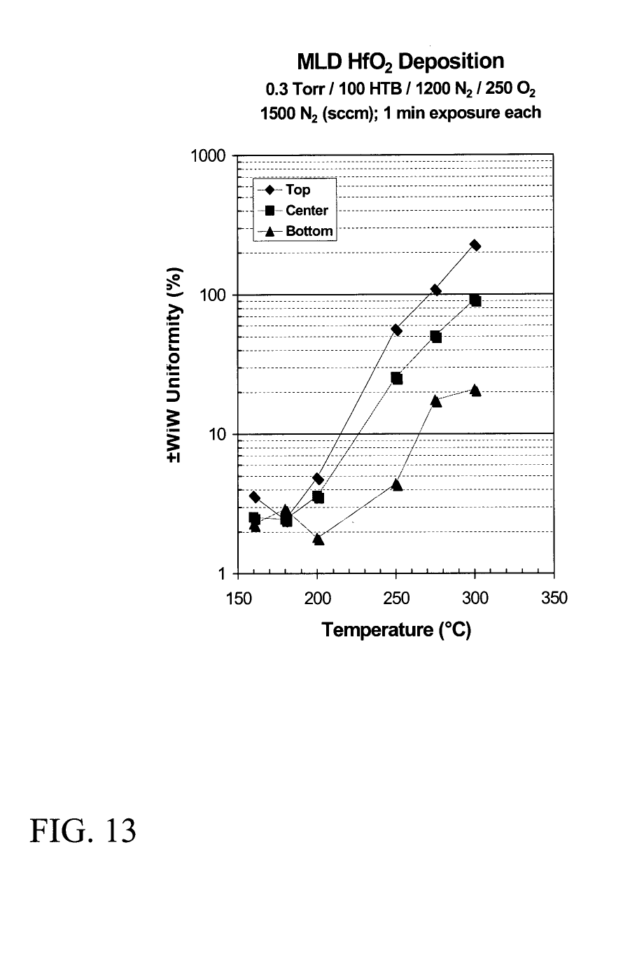

FIG. 12A shows deposition rate of HfO₂ films as a function of substrate temperature according to an embodiment of the invention. Severe Hf(OBu^{t})₄ gas depletion regime at substrate temperatures above about 200° C., where the deposition rate of HfO₂ films onto substrates located near the bottom of the process chamber is higher than onto substrates located near the top of the process chamber. Each gas pulse was 60 sec long. FIG. 12B is an expanded view of FIG. 12A. As seen in FIG. 12B, a self-limiting deposition regime, where the film deposition rate is independent of temperature, is seen for substrate temperatures from about 160° C. to about 180° C. Moreover, FIG. 13 shows WIW uniformity for HfO₂ films deposited according to an embodiment of the invention. As seen in this figure, the WIW uniformity is best when the deposition rate is about 1 A/cycle and the film growth is self-limiting (see in FIGS. 12A and 12B).

FIG. 14 illustrates a computer system 1201 upon which an embodiment of the present invention may be implemented. The computer system 1201 may be used as the controller of FIGS. 1A, 1B, or 2, or a similar controller that may be used with the systems of these figures to perform any or all of the functions described above. The computer system 1201 includes a bus 1202 or other communication mechanism for communicating information, and a processor 1203 coupled with the bus 1202 for processing the information. The computer system 1201 also includes a main memory 1204, such as a random access memory (RAM) or other dynamic storage device (e.g., dynamic RAM (DRAM), static RAM (SRAM), and synchronous DRAM (SDRAM)), coupled to the bus 1202 for storing information and instructions to be executed by processor 1203. In addition, the main memory 1204 may be used for storing temporary variables or other intermediate information during the execution of instructions by the processor 1203. The computer system 1201 further includes a read only memory (ROM) 1205 or other static storage device (e.g., programmable ROM (PROM), erasable PROM (EPROM), and electrically erasable PROM (EEPROM)) coupled to the bus 1202 for storing static information and instructions for the processor 1203.

The computer system 1201 also includes a disk controller 1206 coupled to the bus 1202 to control one or more storage devices for storing information and instructions, such as a magnetic hard disk 1207, and a removable media drive 1208 (e.g., floppy disk drive, read-only compact disc drive, read/write compact disc drive, compact disc jukebox, tape drive, and removable magneto-optical drive). The storage devices may be added to the computer system 1201 using an appropriate device interface (e.g., small computer system interface (SCSI), integrated device electronics (IDE), enhanced-IDE (E-IDE), direct memory access (DMA), or ultra-DMA).

The computer system 1201 may also include special purpose logic devices (e.g., application specific integrated circuits (ASICs)) or configurable logic devices (e.g., simple programmable logic devices (SPLDs), complex programmable logic devices (CPLDs), and field programmable gate arrays (FPGAs)). The computer system may also include one or more digital signal processors (DSPs) such as the TMS320 series of chips from Texas Instruments, the DSP56000, DSP56100, DSP56300, DSP56600, and DSP96000 series of chips from Motorola, the DSP1 600 and DSP3200 series from Lucent Technologies or the ADSP2100 and ADSP21000 series from Analog Devices. Other processors especially designed to process analog signals that have been converted to the digital domain may also be used.

The computer system 1201 may also include a display controller 1209 coupled to the bus 1202 to control a display 1210, such as a cathode ray tube (CRT), for displaying information to a computer user. The computer system includes input devices, such as a keyboard 1211 and a pointing device 1212, for interacting with a computer user and providing information to the processor 1203. The pointing device 1212, for example, may be a mouse, a trackball, or a pointing stick for communicating direction information and command selections to the processor 1203 and for controlling cursor movement on the display 1210. In addition, a printer may provide printed listings of data stored and/or generated by the computer system 1201.

The computer system 1201 performs a portion or all of the processing steps of the invention in response to the processor 1203 executing one or more sequences of one or more instructions contained in a memory, such as the main memory 1204. Such instructions may be read into the main memory 1204 from another computer readable medium, such as a hard disk 1207 or a removable media drive 1208. One or more processors in a multi-processing arrangement may also be employed to execute the sequences of instructions contained in main memory 1204. In alternative embodiments, hard-wired circuitry may be used in place of or in combination with software instructions. Thus, embodiments are not limited to any specific combination of hardware circuitry and software.

As stated above, the computer system 1201 includes at least one computer readable medium or memory for holding instructions programmed according to the teachings of the invention and for containing data structures, tables, records, or other data described herein. Examples of computer readable media are compact discs, hard disks, floppy disks, tape, magneto-optical disks, PROMs (EPROM, EEPROM, flash EPROM), DRAM, SRAM, SDRAM, or any other magnetic medium, compact discs (e.g., CD-ROM), or any other optical medium, punch cards, paper tape, or other physical medium with patterns of holes, a carrier wave (described below), or any other medium from which a computer can read.

Stored on any one or on a combination of computer readable media, the present invention includes software for controlling the computer system 1201, for driving a device or devices for implementing the invention, and for enabling the computer system 1201 to interact with a human user (e.g., print production personnel). Such software may include, but is not limited to, device drivers, operating systems, development tools, and applications software. Such computer readable media further includes the computer program product of the present invention for performing all or a portion (if processing is distributed) of the processing performed in implementing the invention.

The computer code devices of the present invention may be any interpretable or executable code mechanism, including but not limited to scripts, interpretable programs, dynamic link libraries (DLLs), Java classes, and complete executable programs. Moreover, parts of the processing of the present invention may be distributed for better performance, reliability, and/or cost.

The term “computer readable medium” as used herein refers to any medium that participates in providing instructions to the processor 1203 for execution. A computer readable medium may take many forms, including but not limited to, non-volatile media, volatile media, and transmission media. Non-volatile media includes, for example, optical, magnetic disks, and magneto-optical disks, such as the hard disk 1207 or the removable media drive 1208. Volatile media includes dynamic memory, such as the main memory 1204. Transmission media includes coaxial cables, copper wire and fiber optics, including the wires that make up the bus 1202. Transmission media also may also take the form of acoustic or light waves, such as those generated during radio wave and infrared data communications.

Various forms of computer readable media may be involved in carrying out one or more sequences of one or more instructions to processor 1203 for execution. For example, the instructions may initially be carried on a magnetic disk of a remote computer. The remote computer can load the instructions for implementing all or a portion of the present invention remotely into a dynamic memory and send the instructions over a telephone line using a modem. A modem local to the computer system 1201 may receive the data on the telephone line and use an infrared transmitter to convert the data to an infrared signal. An infrared detector coupled to the bus 1202 can receive the data carried in the infrared signal and place the data on the bus 1202. The bus 1202 carries the data to the main memory 1204, from which the processor 1203 retrieves and executes the instructions. The instructions received by the main memory 1204 may optionally be stored on storage device 1207 or 1208 either before or after execution by processor 1203.

The computer system 1201 also includes a communication interface 1213 coupled to the bus 1202. The communication interface 1213 provides a two-way data communication coupling to a network link 1214 that is connected to, for example, a local area network (LAN) 1215, or to another communications network 1216 such as the Internet. For example, the communication interface 1213 may be a network interface card to attach to any packet switched LAN. As another example, the communication interface 1213 may be an asymmetrical digital subscriber line (ADSL) card, an integrated services digital network (ISDN) card or a modem to provide a data communication connection to a corresponding type of communications line. Wireless links may also be implemented. In any such implementation, the communication interface 1213 sends and receives electrical, electromagnetic or optical signals that carry digital data streams representing various types of information.

The network link 1214 typically provides data communication through one or more networks to other data devices. For example, the network link 1214 may provide a connection to another computer through a local network 1215 (e.g., a LAN) or through equipment operated by a service provider, which provides communication services through a communications network 1216. The local network 1214 and the communications network 1216 use, for example, electrical, electromagnetic, or optical signals that carry digital data streams, and the associated physical layer (e.g., CAT 5 cable, coaxial cable, optical fiber, etc). The signals through the various networks and the signals on the network link 1214 and through the communication interface 1213, which carry the digital data to and from the computer system 1201 maybe implemented in baseband signals, or carrier wave based signals. The baseband signals convey the digital data as unmodulated electrical pulses that are descriptive of a stream of digital data bits, where the term “bits” is to be construed broadly to mean symbol, where each symbol conveys at least one or more information bits. The digital data may also be used to modulate a carrier wave, such as with amplitude, phase and/or frequency shift keyed signals that are propagated over a conductive media, or transmitted as electromagnetic waves through a propagation medium. Thus, the digital data may be sent as unmodulated baseband data through a “wired” communication channel and/or sent within a predetermined frequency band, different than baseband, by modulating a carrier wave. The computer system 1201 can transmit and receive data, including program code, through the network(s) 1215 and 1216, the network link 1214, and the communication interface 1213. Moreover, the network link 1214 may provide a connection through a LAN 1215 to a mobile device 1217 such as a personal digital assistant (PDA) laptop computer, or cellular telephone.

Although only certain exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention. For example, in one embodiment of the invention, a pre-determined amount of a reactant gas can be mixed with the flow of the metal-containing precursor gas to improve the properties of the metal-containing film. For example, a small amount of O₂ or NH₃ can mixed with the gas flow. In another embodiment of the invention, a pulse of a reactant gas can be initially flowed in the process chamber prior to flowing the initial pulse of a metal-containing precursor gas can be flowed in the process chamber.

1. A method of forming a metal-containing film on a substrate, the method comprising:
providing a substrate in a process chamber of a batch type processing system;
heating the substrate;
flowing a pulse of a metal-containing precursor in the process chamber;
flowing a pulse of a reactant gas in the process chamber; and
repeating the flowing processes until a metal-containing film with desired film properties is formed on the substrate.

2. The method according to claim 1, wherein the repeating comprises forming a metal-oxide film.

3. The method according to claim 1, wherein the repeating comprises forming at least one of a HfO₂ film, a ZrO₂ film, and a film containing a mixture of HfO₂ and ZrO₂.

4. The method according to claim 1, further comprising flowing a purge gas in the process chamber.

5. The method according to claim 4, wherein the flowing a purge gas comprises flowing a flow rate between about 100 sccm and about 10,000 sccm.

6. The method according to claim 1, further comprising flowing a pulse of a purge gas in the process chamber when the metal-containing precursor and the reactant gas are not flowing.

7. The method according to claim 6, wherein the flowing a pulse of a purge gas comprises flowing a pulse duration between about 1 sec to about 500 sec.

8. The method according to claim 1, wherein the flowing a pulse of a metal-containing precursor comprises flowing a metal-containing precursor and a carrier gas.

9. The method according to claim 8, wherein the flowing a carrier gas comprises a flow rate between about 100 sccm and about 10,000 sccm.

10. The method according to claim 1, wherein the flowing a pulse of a reactant gas comprises flowing a reactant gas and a carrier gas.

11. The method according to claim 1, wherein the flowing a pulse of a reactant gas comprises flowing at least one of an oxidizing gas, a reducing gas, and an inert gas.

12. The method according to claim 11, wherein the flowing a pulse of an oxidizing gas comprises flowing an oxygen-containing gas.

13. The method according to claim 12, wherein the flowing a pulse of an oxygen-containing gas comprises flowing at least one of O₂, O₃, H₂O₂, H₂O, NO, N₂O, and NO₂.

14. The method according to claim 11, wherein the flowing a pulse of a reducing gas comprises flowing at least one of a hydrogen-containing gas, a silicon-containing gas, a boron-containing gas, and a nitrogen-containing gas.

15. The method according to claim 14, wherein the flowing a pulse of a hydrogen-containing gas comprises flowing H₂.

16. The method according to claim 14, wherein the flowing a pulse of a silicon-containing gas comprises flowing at least one of SiH₄, Si₂H₆, Si₂Cl₆, and SiCl₂H₂.

17. The method according to claim 14, wherein the flowing a pulse of a boron-containing gas comprises flowing a gas with the formula BₓH₃ₓ.

18. The method according to claim 14, wherein the flowing a pulse of a the boron-containing gas comprises flowing at least one of BH₃, B₂H₆, and B₃H₉.

19. The method according to claim 14, wherein the flowing a pulse of a nitrogen-containing gas comprises flowing NH₃.

20. The method according to claim 1, wherein the providing comprises providing at least one of a semiconductor substrate, a LCD substrate, and a glass substrate.

21. The method according to claim 20, wherein the providing comprises providing a Si substrate or a compound semiconductor substrate.

22. The method according to claim 1, wherein the providing comprises providing a substrate containing an interfacial film selected from an oxide film, a nitride film, an oxynitride film, or mixtures thereof.

23. The method according to claim 1, wherein the providing comprises providing a batch of about 100 substrates or less.

24. The method according to claim 1, wherein the providing comprises providing a substrate with a substrate diameter greater than about 195 mm.

25. The method according to claim 1, wherein the flowing a pulse of a metal-containing precursor comprises flowing a pulse duration between about 1 sec and about 500 sec.

26. The method according to claim 1, wherein the flowing a pulse of a reactant gas comprises flowing a pulse duration between about 1 sec and about 500 sec.

27. The method according to claim 1, wherein the heating comprises heating the substrate to between about 100° C. and about 600° C.

28. The method according to claim 1, wherein the heating comprises heating the substrate to below about 200° C.

29. The method according to claim 1, wherein the flowing a pulse of a metal-containing precursor further comprises flowing a metal-containing precursor liquid into a vaporizer at a flow rate between about 0.05 ccm and about 1 ccm.

30. The method according to claim 1, wherein the flowing a pulse of a reactant gas comprises flowing a flow rate between about 100 sccm and about 2,000 sccm.

31. The method according to claim 1, further comprising providing a process chamber pressure less than about 10 Torr.

32. The method according to claim 1, further comprising providing a process chamber pressure between about 0.05 Torr and about 2 Torr.

33. The method according to claim 1, further comprising providing a process chamber pressure of about 0.3 Torr.

34. The method according to claim 1, wherein the repeating comprises forming a metal-containing film with a film thickness less than about 1000 A.

35. The method according to claim 1, wherein the repeating comprises forming a metal-containing film with a film thickness less than about 200 A.

36. The method according to claim 1, wherein the repeating comprises forming a metal-containing film with a film thickness less than about 50 A.

37. The method according to claim 1, further comprising annealing the metal-containing film at a temperature between about 150° C. and about 1000° C.

38. The method according to claim 1, further comprising depositing an electrode film comprising at least one of W, Al, TaN, TaSiN, HfN, HfSiN, TiN, TiSiN, Re, Ru, Si, poly-Si, and SiGe.

39. The method according to claim 1, further comprising flowing a pulse of a nitrogen-containing gas in the process chamber.

40. The method according to claim 39, wherein the repeating comprises forming a metal-oxynitride film.

41. The method according to claim 39, wherein the repeating comprises forming at least one of a HfₓO_{z}N_{w} film, a ZrₓO_{z}N_{w} film, and a film containing a mixture of HfₓO_{z}N_{w} and ZrₓO_{z}N_{w}.

42. The method according to claim 39, wherein:
the flowing a pulse of a metal-containing precursor comprises flowing at least one pulse,
the flowing a pulse of a reactant gas comprises flowing at least one pulse, and
the flowing a pulse of a nitrogen-containing gas comprises at least one pulse.

43. The method according to claim 1, further comprising flowing a pulse of a silicon-containing gas in the process chamber.

44. The method according to claim 43, wherein the repeating comprises forming a metal-silicate film.

45. The method according to claim 43, wherein the repeating comprises forming at least one of a HfₓSi_{y}O_{z} film, a ZrₓSi_{y}O_{z} film, and a film containing a mixture of HfₓSi_{y}O_{z} and ZrₓSi_{y}O_{z}.

46. The method according to claim 43, wherein:
the flowing a pulse of a metal-containing precursor comprises flowing at least one pulse,
the flowing a pulse of a reactant gas comprises flowing at least one pulse, and
the flowing a pulse of a silicon-containing gas comprises at least one pulse.

47. The method according to claim 43, further comprising flowing a pulse of nitrogen-containing gas in the process chamber

48. The method according to claim 47, wherein the repeating comprises forming a nitrogen-containing metal-silicate film.

49. The method according to claim 47, wherein the repeating comprises forming at least one of a HfₓSi_{y}O_{z}N_{w} film, a ZrₓSi_{y}O_{z}N_{w} film, and a film containing a mixture of HfₓSi_{y}O_{z}N_{w} and ZrₓSi_{y}O_{z}N_{w}.

50. The method according to claim 47, wherein:
the flowing a pulse of a metal-containing precursor comprises flowing at least one pulse,
the flowing a pulse of a reactant gas comprises flowing at least one pulse,
the flowing a pulse of a nitrogen-containing gas comprises at least one pulse, and
the flowing a pulse of a silicon-containing gas comprises at least one pulse.

51. The method according to claim 1, wherein the repeating comprises forming a metal-containing film in a self-limiting process.

52. The method according to claim 1, wherein the heating comprises heating the substrate under isothermal heating conditions.

53. The method according to claim 1, wherein the flowing a pulse of a metal-containing precursor comprises flowing a metal alkoxide.

54. The method according to claim 53, wherein the flowing a metal alkoxide comprises flowing at least one of M(OMe)₄, M(OEt)₄, M(OPr)₄, and M(OBu^{t})₄.

55. The method according to claim 53, wherein the flowing a metal alkoxide comprises flowing at least one of a hafnium alkoxide and a zirconium alkoxide.

56. The method according to claim 53, wherein the flowing a metal alkoxide comprises flowing at least one of Hf(OBu^{t})₄ and Zr(OBu^{t})₄.

57. The method according to claim 53, wherein the flowing a metal alkoxide comprises flowing at least one of M(OR)₂(mmp)₂ and M(mmp)₄.

58. The method according to claim 1, wherein the flowing a pulse of a metal-containing precursor comprises flowing a metal alkylamide.

59. The method according to claim 58, wherein the flowing a metal alkylamide comprises flowing at least one of a hafnium alkylamide and a zirconium alkylamide.

60. The method according to claim 58, wherein the flowing a metal alkylamide comprises at least one of Hf(NEt₂)₄, Hf(NEtMe)₄, Zr(NEt₂)₄, and Zr(NEtMe)₄.

61. The method according to claim 1, wherein:
the providing comprises providing a plurality of substrates in said process chamber, and
the repeating comprises forming an HfO₂ film on each of the plurality of substrates, the plurality of substrates having a thickness of about 30 A to about 50 A and a WIW uniformity of about 10% to about 15%.

62. The method according to claim 1, wherein:
the providing comprises providing a plurality of substrates in said process chamber, and
the repeating comprises forming an HfO₂ film on each of the plurality of substrates, the plurality of substrates having a thickness of about 20 A to about 50 A and a WIW uniformity of about 20% or less.

63. The method according to claim 1, wherein:
the providing comprises providing a plurality of substrates in said process chamber,
the repeating comprises forming an HfO₂ film on each of the plurality of substrates, and
the heating comprises heating within a temperature range at which film deposition rate is independent of temperature.

64. The method according to claim 63, wherein said heating comprises heating within a temperature range of about 160 to 180° C.

65. A computer readable medium containing program instructions for execution on a processor, which when executed by the processor, cause a batch substrate processing apparatus to perform the steps in the method recited in claim 1.

66. A system for batch processing a plurality of substrates, comprising:
means for providing a substrate in a process chamber of a batch type processing system;
means for heating the substrate;
means for flowing a pulse of a metal-containing precursor in the process chamber;
means for flowing a pulse of a reactant gas in the process chamber; and
repeating the flowing processes until a metal-containing film with desired film properties is formed on the substrate.

67. A processing tool, comprising:
a batch type processing system configured to form a metal-containing film;
a transfer system configured to provide a substrate in a process chamber of the batch type processing system;
a heater for heating the substrate;
a gas injection system configured to flow a pulse of a metal-containing precursor gas in the process chamber, flow a pulse of a reactant gas in the process chamber, and repeat the flowing processes until a metal-containing film with desired film properties is formed on the substrate; and
a controller configured to control the processing tool.

68. The processing tool according to claim 67, further comprising a processing system configured to form an interfacial film on the substrate.

69. The processing tool according to claim 67, further comprising a processing system configured to anneal a film on the substrate.

70. The processing tool according to claim 67, further comprising a processing system configured to perform a preclean process on the substrate.

71. The processing tool according to claim 67, wherein the batch type processing system comprises at least one process tube.

72. The processing tool according to claim 67, further comprising a process monitoring system.

73. The processing tool according to claim 67, wherein the gas injection system is further configured to flow at least one of a carrier gas and a purge gas.

74. The processing tool according to claim 67, wherein the tool is configured to form a metal-containing film comprises at least one of metal-oxide film, a metal-oxynitride film, a metal-silicate film, and a nitrogen-containing metal-silicate film.

75. The method according to claim 67, wherein the gas injection system is configured to flow a metal-containing precursor comprising at least one of an alkoxide and an alkylamide.

76. The method according to claim 67, wherein the gas injection system is configured to flow a metal-containing precursor comprising at least one of hafnium and zirconium.

77. The processing tool according to claim 67, wherein the gas injection system is further configured to flow at least one of a pulse of a nitrogen-containing gas and a pulse of a silicon-containing gas.
